(19) United States
(12) Patent Application Publication
(10) Pub. No.: US 2024/0429218 A1
(43) Pub. Date: Dec. 26, 2024

(54) DISPLAY DEVICE

(71) Applicant: Samsung Display Co., LTD., Yongin-si (KR)

(72) Inventors: OUKJAE LEE, Yongin-si (KR); TAEGON KIM, Yongin-si (KR); HYUNYOUNG KIM, Yongin-si (KR); JONG-RYUK PARK, Yongin-si (KR)

(21) Appl. No.: 18/618,854

(22) Filed: Mar. 27, 2024

(30) Foreign Application Priority Data
Jun. 22, 2023 (KR) 10-2023-0080593

(51) Int. Cl. H01L 25/16; H01L 23/544

(52) U.S. Cl. CPC H01L 25/167; H01L 23/544; H01L 2223/54426

(57) ABSTRACT

A display device includes: a display panel including a display area and a surrounding area surrounding the display area; a gate driver in the surrounding area of the display panel; and a bottom panel below the display panel and including a cutout area having a width in a range of 1 micrometers (μm) to 160 μm in a first direction in a plan view.

### CROSS-REFERENCE TO RELATED APPLICATION

The present application claims priority to and the benefit of Korean Patent Application No. 10-2023-0080593, filed on Jun. 22, 2023, in the Korean Intellectual Property Office, the entire disclosure of which is incorporated herein by reference.

### BACKGROUND

### 1. Field

Aspects of some embodiments relate generally to a display device.

### 2. Description of the Related Art

The importance of display devices is increasing with the development of multimedia. In response to this, various types of display devices such as Organic Light Emitting Display (OLED) and Liquid Crystal Display (LCD) are being used.

The driving transistor of such a display device has unique characteristics with respect to threshold voltage and mobility. The unique characteristics of each driving transistor may vary between pixels due to process deviation, deterioration, and the like. Such deviation may cause luminance deviation and thus decrease image quality.

The above information disclosed in this Background section is only for enhancement of understanding of the background and therefore the information discussed in this Background section does not necessarily constitute prior art.

### SUMMARY

Aspects of some embodiments relate generally to a display device. For example, aspects of some embodiments relate to a display device configured to display visual information.

Aspects of some embodiments include a display device with relatively improved display quality.

A display device according to some embodiments of the present invention may include a display panel including a display area and a surrounding area surrounding the display area, a gate driver in the surrounding area of the display panel, and a bottom panel under the display panel, including a cutout area having a width of about 1 μm to about 160 μm in a first direction on a plane (or in a plan view).

According to some embodiments, the gate driver and the cutout area may be spaced apart in the first direction on a plane.

According to some embodiments, on a plane, a separation distance between the gate driver and the cutout area in the first direction may be about 280 μm to about 1000 μm.

According to some embodiments, the separation distance may be about 1.75 to about 1000 times the width of the cutout area in the first direction.

According to some embodiments, a width of the cutout area in the first direction may be smaller than a width of the cutout area in a second direction intersecting the first direction.

According to some embodiments, the display panel may further include alignment mark in the surrounding area of the display panel, and the number of alignment marks may be equal to the number of cutout areas.

According to some embodiments, the alignment mark and the cutout area may correspond one-to-one.

According to some embodiments, the alignment mark and the cutout area may overlap on a plane.

According to some embodiments, the cutout area may be spaced apart from the display area in the first direction on a plane with the gate driver interposed therebetween.

According to some embodiments, a planar area of the bottom panel may be smaller than a planar area of the display panel.

According to some embodiments, the gate driver may include at least one transistor, and the transistor may include an active pattern including a semiconductor material.

According to some embodiments, the gate driver may include a PMOS transistor.

According to some embodiments, the gate driver may include an NMOS transistor.

According to some embodiments, the display panel may further include a substrate below the active pattern, and the substrate may include a first substrate, a first barrier layer on the first substrate, a second substrate on the first barrier layer, and may include a second barrier layer on the second substrate.

According to some embodiments, the first substrate and the second substrate may include polyimide.

A display device according to some embodiments of the present invention may include a display panel including a display area and a surrounding area surrounding the display area, a gate driver in the surrounding area of the display panel and including at least one transistor including an active pattern including semiconductor material, a metal layer below the active pattern and at least partially overlaps the active pattern on a plane, and bottom panel below the display panel, and having a width on a plane in the first direction of about 1 μm to about 160 μm.

According to some embodiments, the display panel may further include a substrate below the active pattern, and the substrate may include a first substrate, a first barrier layer on the first substrate, a second substrate on the first barrier layer, and a second barrier layer on the second substrate, and the metal layer may be between the second barrier layer and the active pattern.

According to some embodiments, the gate driver and the cutout area may be arranged to be spaced apart from each other in the first direction on a plane, and a separation distance between the gate driver and the cutout area in the first direction may be about 280 μm to about 1000 μm on a plane.

According to some embodiments, the separation distance may be about 1.75 to about 1000 times the width of the cutout area in the first direction.

According to some embodiments, a width of the cutout area in the first direction may be smaller than a width of the cutout area in a second direction intersecting the first direction.

Therefore, a phenomenon in which light irradiated through the cutout areas reaches the gate driver may be relatively reduced or prevented. Accordingly, changes in the electrical characteristics of the transistor in the gate driver due to polarization of the substrate included in the display panel may be relatively reduced or prevented. Accordingly, the occurrence of light spots in the display area according to changes in the electrical characteristics of the transistor may be relatively reduced or prevented. Accordingly, the display quality of the display device may be relatively improved.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a plan view showing a display device according to some embodiments of the present invention.

FIG. 2 is a cross-sectional view taken along the line I-I′ of the display device of FIG. 1 according to some embodiments of the present invention.

FIG. 3 is a cross-sectional view showing an example of the display panel of FIG. 2 according to some embodiments of the present invention.

FIG. 4 is a bottom view showing an example of a display panel and bottom panel of FIG. 2 according to some embodiments of the present invention.

FIG. 5 is an enlarged view of portion A of FIG. 4 according to some embodiments of the present invention.

FIG. 6 is a cross-sectional view showing a transistor included in the gate driver of FIG. 5 according to some embodiments of the present invention.

FIG. 7 is a cross-sectional view showing another example of FIG. 6 according to some embodiments of the present invention.

### DETAILED DESCRIPTION

Illustrative, non-limiting embodiments will be more clearly understood from the following detailed description in conjunction with the accompanying drawings.

In this specification, a plane may be defined by a first direction D1 and a second direction D2 intersecting the first direction D1. For example, the second direction D2 may be perpendicular to the first direction D1. Additionally, a third direction D3 may be the normal direction of the plane. That is, the third direction D3 may be perpendicular to the plane formed by the first direction D1 and the second direction D2.

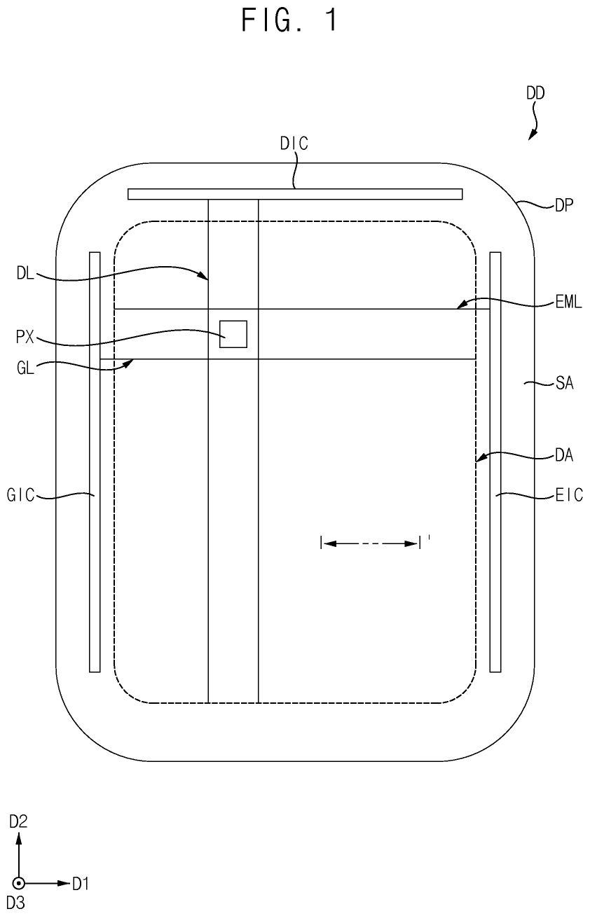

FIG. 1 is a plan view showing a display device according to some embodiments of the present invention.

Referring to FIG. 1, a display device DD may include a display area DA and a surrounding area SA. The display area DA may be surrounded by the surrounding area SA. According to some embodiments, the surrounding area SA may be located in a periphery or outside a footprint of the display area DA.

The display area DA may be an area that may display images by generating light or adjusting the transmittance of light provided from an external light source. The surrounding area SA may be an area that may not display images. However, embodiments according to the present invention are not necessarily limited thereto, and the surrounding area SA according to some embodiments may display images.

The display device DD may include a gate driver GIC, a data driver DIC, an emission driver EIC, gate lines GL, data lines DL, and emission control lines EML.

The gate driver GIC may be located in the surrounding area SA. For example, the gate driver GIC may be located on one side of the display area DA. However, embodiments according to the present invention are not necessarily limited thereto, and the gate driver GIC may be located on both sides of the display area DA. The gate driver GIC corresponds to the gate lines GL and may apply a gate signal to the gate lines GL. Although one gate driver is shown in FIG. 1, embodiments according to the present invention are not necessarily limited thereto, and in another example, the display device DD may include a plurality of gate drivers.

The data driver DIC may be located in the surrounding area SA. For example, the data driver DIC may be placed on one side of the display area DA. However, embodiments according to the present invention are not necessarily limited thereto, and the data driver DIC may be located on both sides of the display area DA. The data driver DIC may correspond to the data lines DL and apply a data signal to the data lines DL. Although one data driver is shown in FIG. 1, embodiments according to the present invention are not necessarily limited thereto, and in another example, the display device DD may include a plurality of data drivers.

The light emission driver EIC may be located in the surrounding area SA. For example, the light emission driver EIC may be located on one side of the display area DA. However, embodiments according to the present invention are not necessarily limited thereto, and the light emission driver EIC may be located on both sides of the display area DA. The emission driver EIC may correspond to the emission control lines EML and may apply an emission control signal to the emission control lines EML. Although one light emitting driver is shown in FIG. 1, embodiments according to the present invention are not necessarily limited thereto, and in another example, the display device DD may include a plurality of light emitting drivers.

The gate lines GL may be located in the display area DA. The gate lines GL correspond to the gate driver GIC and may extend along the first direction D1. The gate lines GL may be arranged to be spaced apart along the second direction D2. The gate lines GL may transmit the gate signal to the pixel PX.

The data lines DL may be located in the display area DA. The data lines DL correspond to the data driver DIC and may extend along the second direction D2. The data lines DL may be arranged to be spaced apart along the first direction D1. The data lines DL may transmit the data signal to the pixel PX.

The emission control lines EML may be located in the display area DA. The emission control lines EML correspond to the emission driver EIC and may extend along the first direction D1. The emission control lines EML may be arranged to be spaced apart along the second direction D2. The emission control lines EML may transmit the emission control signal to the pixel PX.

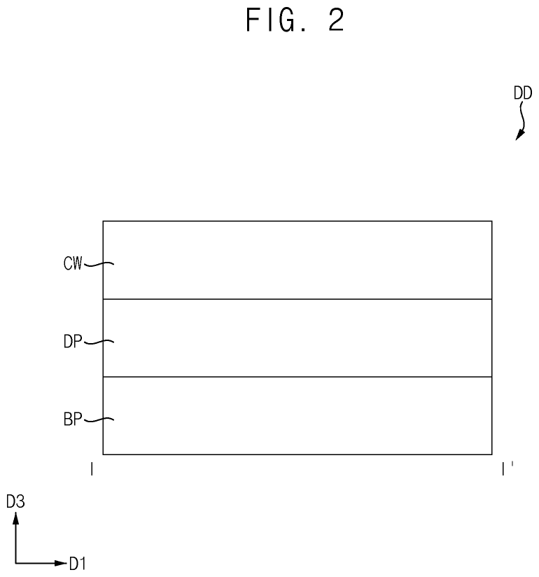

FIG. 2 is a cross-sectional view taken along the line I-I′ of the display device of FIG. 1.

Referring to FIG. 2, the display device DD may include a bottom panel BP, a display panel DP, and a cover window CW.

The bottom panel BP may be located below the display device DD. The bottom panel BP may be arranged to maintain the rigidity of the display device DD. For example, the bottom panel BP may prevent external moisture or contaminants from penetrating into the display device DD and to absorb external shock or impacts.

Examples of materials of bottom panel BP may include polyethersulfone (PES), polyacrylate, polyetherimide (PEI), polyethylenenaphthalate (PEN), polyethylene terephthalate (PET), polyphenylene sulfide (PPS), polyarylate, polyimide (PI), polycarbonate (PC), polyarylene ether sulfone, and the like. These may be used alone or in combination with each other.

The display panel DP may be located on the bottom panel BP. The display panel DP is a panel that displays a screen, and may include an organic light emitting display panel (OLED) including an organic light emitting layer, a micro light emitting diode display panel using micro LED, and a quantum dot light emitting device including a quantum dot light emitting layer, or an inorganic light emitting display panel using an inorganic light emitting device containing an inorganic semiconductor.

A cover window CW may be located on the display panel DP. The cover window CW may cover the front surface of the display device DD and protect the display panel DP. The cover window CW may include a transparent material capable of emitting an image. For example, the cover window CW may include ultra-thin glass (UTG), polymethyl methacrylate (PMMA), and the like.

According to some embodiments, the bottom panel BP, display panel DP, and cover window CW of the display device DD may be attached to each other by an adhesive layer. For example, the adhesive layer may be located on the bottom panel BP and attached to the display panel DP, and the adhesive layer may be located on the display panel DP and attached to the cover window CW. However, embodiments according to the present invention are not necessarily limited thereto, and the adhesive layer may be omitted.

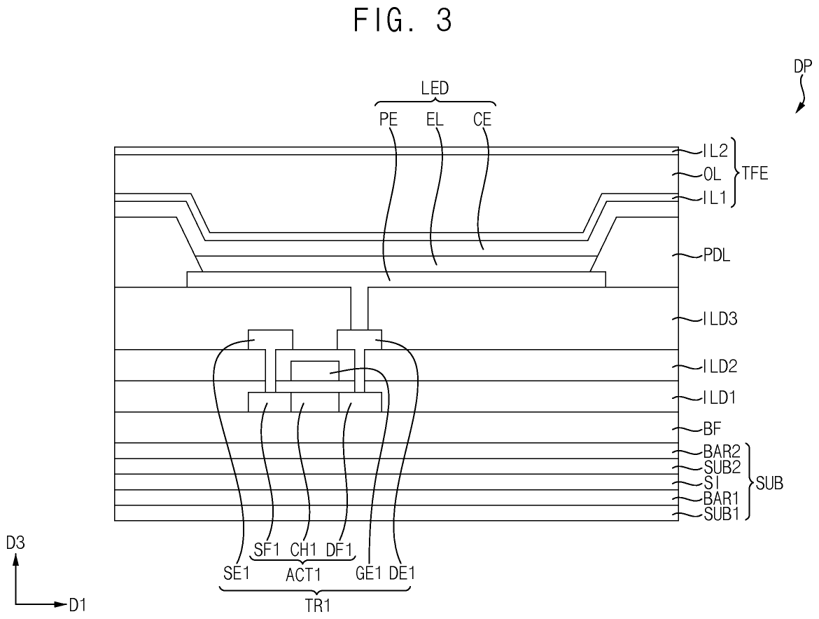

FIG. 3 is a cross-sectional view showing an example of the display panel of FIG. 2.

Referring to FIG. 2 and FIG. 3, the display panel DP may include a substrate SUB, a buffer layer BF, first to third interlayer insulating films ILD1, ILD2, and ILD3, a first transistor TR1, a light emitting device. LED, a pixel defining layer PDL, and a thin film encapsulation layer TFE.

The substrate SUB may include a first substrate SUB1, a first barrier layer BAR1, a silicon layer SI, a second substrate SUB2, and a second barrier layer BAR2.

The first substrate SUB1 may include a polymer material. Examples of the polymer material included in the first substrate SUB1 may include polyimide, polyethersulphone, polyacrylate, polyarylate, polyetherimide, polyethylene naphthalate, polyethylene terephthalate, polyphenylene sulfide, polyallylate, polycarbonate, cellulose triacetate, cellulose acetate propionate, and the like. These may be used alone or in combination with each other. However, the polymer material is not limited thereto.

The first barrier layer BAR1 may be located on the first substrate SUB1. The first barrier layer BAR1 may cover the first substrate SUB1. The first barrier layer BAR1 may prevent diffusion of impurity ions and may prevent penetration of moisture, air, or other contaminants. The first barrier layer BAR1 may include an inorganic material. Examples of the inorganic material may include silicon oxide (SiOx), silicon nitride (SiNx), and silicon oxynitride (SiOxNy). These may be used alone or in combination with each other.

The silicon layer SI may be located on the first barrier layer BAR1. The silicon layer SI may include amorphous silicon (a-Si), poly-silicon (poly-Si), and the like. These may be used alone or in combination with each other.

The second substrate SUB2 may be located on the silicon layer SI. The second substrate SUB2 may include substantially a same material as the first substrate SUB1.

The second barrier layer BAR2 may be located on the second substrate SUB2. The second barrier layer BAR2 may include substantially a same material as the first barrier layer BAR1.

According to some embodiments, a polarization phenomenon may occur in the first substrate SUB1 and/or the second substrate SUB2 as the bottom panel BP has a polarity. For example, as the bottom panel BP is positively charged, negative charges may accumulate at the bottom of the first substrate SUB1 and/or the second substrate SUB2 and positive charges may accumulate at the top of the first substrate SUB1 and/or the second substrate SUB2. For another example, as the bottom panel BP is negatively charged, positive charges may accumulate at the bottom of the first substrate SUB1 and/or the second substrate SUB2 and negative charges may accumulate at the top of the first substrate SUB1 and/or the second substrate SUB2.

Meanwhile, the reasons the bottom panel BP has polarity may vary. For example, the bottom panel BP may be placed and moved on an electrostatic chuck when coupled to the display panel DP, and the bottom panel BP may be polarized by the electrostatic chuck. For another example, the bottom panel BP may be polarized by light irradiated to the bottom panel BP from outside the display device DD. For still another example, the bottom panel BP may be polarized by light emitted from the light emitting device LED in the display panel DP.

The buffer layer BF may be located on the substrate SUB. The buffer layer BF may prevent foreign substances penetrating through the substrate SUB from being transferred to the first transistor TR1. In addition, the buffer layer BF may improve the flatness of the substrate SUB, and accordingly, the buffer layer BF may form a uniform plane on which the first transistor TR1 is located. The buffer layer BF may include an inorganic insulating material.

The first transistor TR1 may be located on the buffer layer BF. The first transistor TR1 may include a first source electrode SE1, a first drain electrode DE1, a first active pattern ACT1, and a first gate electrode GE1.

The first active pattern ACT1 may be located on the buffer layer BF. The first active pattern ACT1 may include a silicon-based semiconductor material or an oxide-based semiconductor material. For example, the silicon-based semiconductor material included in the first active pattern ACT1 may include amorphous silicon, polycrystalline silicon, and the like. In addition, the oxide-based semiconductor material included in the first active pattern ACT1 may include zinc oxide (ZnOx), tin oxide (SnOx), indium oxide (InOx), indium-zinc oxide (IZO), and indium-gallium oxide (IGO), zinc-tin oxide (ZnSnxOy), and indium-gallium-zinc oxide (IGZO). These may be used alone or in combination with each other.

The first active pattern ACT1 may include a first source region SF1, a first drain region DF1, and a first channel region CH1 located between the first source region SF1 and the first drain region DF1. The first source region SF1 and the first drain region DF1 may be doped with impurity ions. For example, the first source region SF1 and the first drain region DF1 may be doped with P-type impurity ions. For another example, the first source region SF1 and the first drain region DF1 may be doped with N-type impurity ions.

The first interlayer insulating layer ILD1 may be located on the buffer layer BF covering the first active pattern ACT1. The first interlayer insulating layer ILD1 may include silicon oxide (SiOx), silicon nitride (SiNx), silicon oxynitride (SiNxOy), and the like.

The first gate electrode GE1 may be located on the first interlayer insulating layer ILD1. The first gate electrode GE1 may overlap the first channel region CH1 on a plane (or in a plan view, e.g., a view perpendicular to a plane parallel to a display surface of the display device DD, e.g., when viewed from the third direction D3). The first gate electrode GE1 may include a conductive material. For example, the first gate electrode GE1 may include metal, alloy, conductive metal oxide, transparent conductive material, and the like. For example, the first gate electrode GE1 may include silver (Ag), an alloy containing silver, molybdenum (Mo), an alloy containing molybdenum, aluminum (Al), an alloy containing aluminum, aluminum nitride. (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and the like. These may be used alone or in combination with each other.

The second interlayer insulating layer ILD2 may be located on the first interlayer insulating layer ILD1 covering the first gate electrode GE1. The second interlayer insulating layer ILD2 may include a silicon compound, a metal oxide, and the like. For example, the second interlayer insulating film ILD2 may include silicon oxide (SiOx), silicon nitride (SiNx), silicon oxynitride (SiNxOy), and the like.

The first source electrode SE1 and the first drain electrode DE1 may be located on the second interlayer insulating layer ILD2. For example, the first source electrode SE1 and the first drain electrode DE1 may be electrically connected to the first active pattern ACT1 respectively. For example, the first source electrode SE1 may contact the first source region SF1, and the first drain electrode DE1 may contact the first drain region DF1. The signal transmitted to the first source electrode SE1 may be transmitted to the first drain electrode DE1 through the first active pattern ACT1. The first source electrode SE1 and the first drain electrode DE1 may include metal, alloy, conductive metal oxide, transparent conductive material, and the like.

The third interlayer insulating layer ILD3 may be located on the first interlayer insulating layer ILD2 covering the first source electrode SE1 and the first drain electrode DE1. The third interlayer insulating layer ILD3 may include a silicon compound, a metal oxide, and the like. For example, the third interlayer insulating layer ILD3 may include silicon oxide (SiOx), silicon nitride (SiNx), silicon oxynitride (SiNxOy), and the like.

The light emitting device LED may be located on the third interlayer insulating layer ILD3. The light emitting device LED may include a pixel electrode PE, a light emitting layer EL, and a common electrode CE. For example, the light emitting layer EL may be located on the pixel electrode PE, and the common electrode CE may be located on the light emitting layer EL.

The pixel electrode PE may be located on the third interlayer insulating layer ILD3. The pixel electrode PE may penetrate the third interlayer insulating layer ILD3 and may be electrically connected to the first drain electrode DE1. The pixel electrode PE may include a transparent conductive material. For example, the pixel electrode PE may include at least one of Indium Tin Oxide, Indium Zinc Oxide, Indium Gallium Zinc Oxide, Fluorine Zinc Oxide, Gallium Zinc Oxide, or tin oxide.

The pixel defining layer PDL may be located on the pixel electrode PE. For example, the pixel defining layer PDL may expose at least a portion of the pixel electrode PE. The pixel defining layer PDL may include an inorganic insulating material or an organic insulating material.

The light emitting layer EL may be located on the pixel electrode PE. The light emitting layer EL may emit light. The light emitting layer EL may include a hole injection layer, a hole transport layer, an organic light emitting layer, an electron transport layer, and an electron injection layer. Also, the light emitting layer EL may include an inorganic material.

The common electrode CE may be located on the light emitting layer EL. The common electrode CE may be located on the entire surface of the display area DA. For example, the common electrode CE may include metal, alloy, metal nitride, conductive metal oxide, transparent conductive material, and the like. These may be used alone or in combination with each other.

The thin film encapsulation layer TFE may be located on the common electrode CE. The thin film encapsulation layer TFE may protect the light emitting device LED from external moisture, heat, shock, and the like. The thin film encapsulation layer TFE may include a first inorganic layer IL1, an organic layer OL, and a second inorganic layer IL2. However, embodiments according to the present invention are not necessarily limited thereto. The thin film encapsulation layer TFE may include a plurality of organic layers and inorganic layers arranged alternately.

The first inorganic layer IL1 may be located on the common electrode CE. The first inorganic layer IL1 may include SiN, SiO, and SiON. These may be used alone or in combination with each other.

The organic layer OL may be located on the first inorganic layer IL1. The organic layer OL may include acrylic resin, methacrylic resin, polyisoprene, vinyl resin, epoxy resin, urethane resin, cellulose resin, siloxane resin, polyimide resin, polyamide resin, and perylene resin. These may be used alone or in combination with each other.

The second inorganic layer IL2 may be located on the organic layer OL. The second inorganic layer IL2 may include SiN, SiO, and SiON. These may be used alone or in combination with each other.

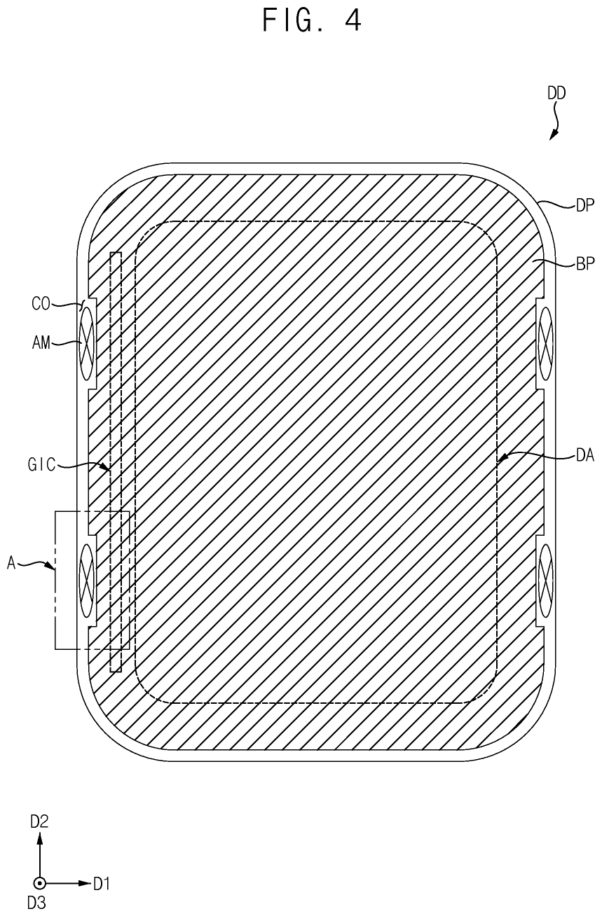

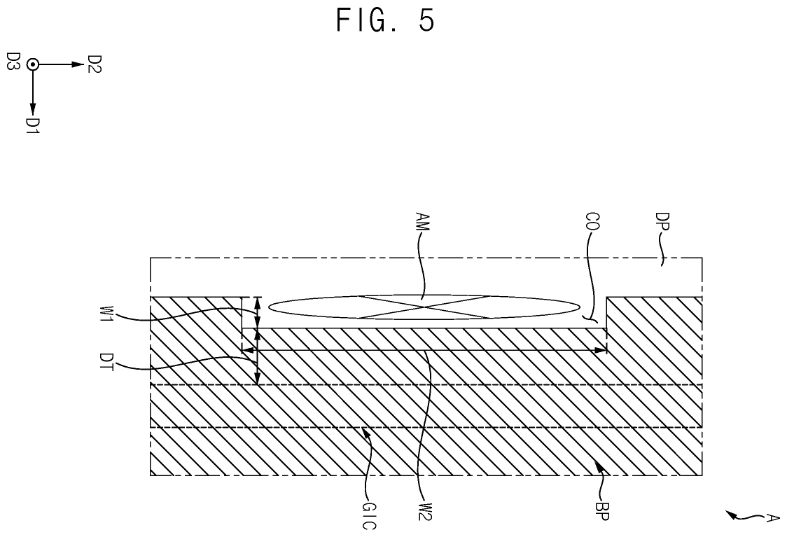

FIG. 4 is a bottom view showing an example of the display panel and bottom panel of FIG. 2. FIG. 5 is an enlarged view of portion A of FIG. 4. For example, FIG. 4 is a bottom view showing the bottom panel BP located on the bottom of the display panel DP.

Referring to FIGS. 4 and 5, the bottom panel BP may be located below the display panel DP. For example, the display panel DP and the bottom panel BP may be attached through the adhesive layer located between the display panel DP and the bottom panel BP.

The bottom panel BP may include a plurality of cutout areas CO. The cutout areas CO may be defined as areas where a portion of the bottom panel BP is cut out.

According to some embodiments, any two or more of the cutout areas CO may be located on one side of the bottom panel BP. For example, two or more of the cutout areas CO located on one side of the bottom panel BP may be spaced apart from each other along the second direction D2. In addition, two or more of the cutout areas CO may be located on the other side of the bottom panel BP opposite the one side to the first direction D1. For example, two or more of the cutout areas CO located on the other side of the bottom panel BP may be spaced apart from each other along the second direction D2. However, embodiments according to the present invention are not necessarily limited thereto. For example, there may be only one cutout area on each of one side and the other side of the bottom panel BP.

In addition, in FIG. 4, the cutout areas CO are shown as being located on one side and the other side of the bottom panel BP facing in the first direction D1, However, the cutout areas CO may be located on both sides of the bottom panel BP facing in the second direction D2. In addition, in FIG. 4, the bottom panel BP is shown as including four cutout areas CO, but embodiments according to the present invention are not necessarily limited thereto, and the bottom panel BP may have three or fewer cutout areas CO or five or more cutout areas CO.

According to some embodiments, each of the cutout areas CO adjacent to the gate driver GIC among the cutout areas CO may be spaced apart from the display area DA in the first direction D1 with the gate driver GIC interposed therebetween on a plane. That is, the gate driver GIC may be located closer to the display area DA than the cutout areas CO adjacent to the gate driver GIC. However, embodiments according to the present invention are not necessarily limited thereto.

The display panel DP may include a plurality of alignment marks AM.

According to some embodiments, any two or more of the alignment marks AM may be located on one side of the display panel DP. For example, two or more of the alignment marks AM located on one side of the display panel DP may be spaced apart from each other along the second direction D2. Additionally, two or more of the alignment marks AM may be located on the other side of the display panel DP opposite the one side to the first direction D1. For example, two or more of the alignment marks AM located on the other side of the display panel DP may be spaced apart from each other along the second direction D2. However, embodiments according to the present invention are not necessarily limited thereto. For example, there may be only one alignment mark on each of one side and the other side of the display panel DP.

In addition, in FIG. 4, the alignment marks AM are shown as being located on one side and the other side of the display panel DP facing in the first direction D1, but the alignment marks AM may be located on both sides of the display panel DP facing in the second direction D2. Additionally, in FIG. 4, the display panel DP is shown as including four alignment marks AM, embodiments according to the present invention are not necessarily limited thereto, and the display panel DP may include 3 or less or 5 or more alignment marks AM.

According to some embodiments, the number of the alignment marks AM and the number of the cutout areas CO may be the same. That is, the alignment marks AM and the cutout areas CO may correspond one-to-one. For example, the alignment marks AM and the cutout areas CO may each overlap on a plane.

According to some embodiments, in the process of attaching the bottom panel BP to the display panel DP, the cutout areas CO and the alignment marks AM may improve a degree of alignment between the display panel DP and the bottom panels BP. For example, the display panel DP and the lower panel BP may be aligned so that the alignment marks AM of the display panel DP and the cutout areas CO of the lower panel BP correspond to each other and overlap on a plane. For example, the display panel DP and the bottom panel BP may be aligned so that the alignment marks AM are not covered by the bottom panel BP. In other words, the display panel DP and the bottom panel BP may be aligned so that the alignment marks AM are exposed by the cutout areas CO.

According to some embodiments, a width W1 of each of the cutout areas CO in the first direction D1 on a plane (or in a plan view) may be about 160 (micrometers) um or less. For example, the width W1 of each of the cutout areas CO in the first direction D1 on a plane may be about 1 μm to about 160 μm, preferably about 100 μm to about 160 μm, more preferably about 150 μm to about 160 μm.

According to some embodiments, each of the cutout areas CO adjacent to the gate driver GIC among the cutout areas and the gate driver GIC are spaced apart from each other in the first direction D1. For example, each of the cutout areas CO adjacent to the gate driver GIC and the gate driver GIC may be placed with a separation distance DT in the first direction D1.

The separation distance DT may be about 280 μm or more. For example, the separation distance DT may be about 280 μm to about 1000 μm, preferably about 280 μm to about 350 μm, and more preferably about 280 μm to about 300 μm.

According to some embodiments, the separation distance DT may be about 1.75 times to about 1000 times the width of each of the cutout areas CO in the first direction D1, preferably from about 1.75 times to 3.5 times, more preferably from about 1.75 times to about 2 times. That is, when the separation distance DT is the maximum value of about 1000 μm and the width W1 of each of the cutout areas CO in the first direction D1 is the minimum value of about 1 μm, the separation distance DT may be about 1000 times the width W1 of each of the cutout areas CO in the first direction D1. Similarly, when the separation distance DT is a minimum value of about 280 μm and the width W1 of each of the cutout areas CO in the first direction D1 is a maximum value of about 160 μm, the separation distance DT may be about 1.75 times the width W1 of each of the cutout areas CO in the first direction D1.

According to some embodiments, the width W1 of each of the cutout areas CO in the first direction may be smaller than the width W2 in the second direction D2. However, embodiments according to the present invention are not limited thereto.

According to some embodiments, the area of the bottom panel BP may be smaller than the area of the display panel DP. That is, the bottom panel BP may cover a portion of the display panel DP. However, embodiments according to the present invention are not limited thereto.

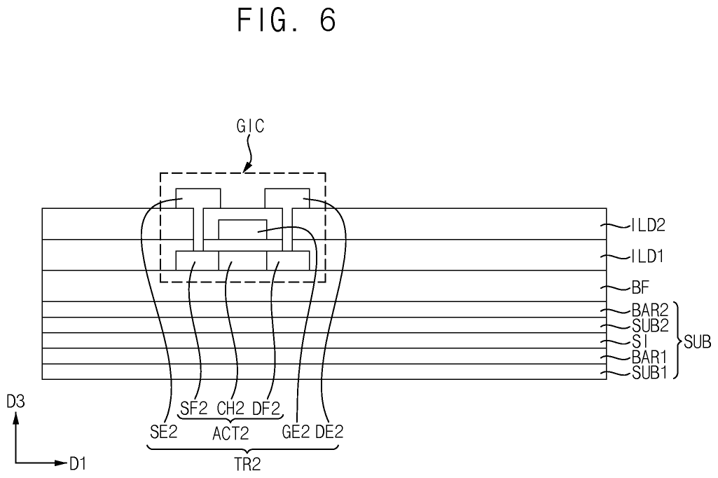

FIG. 6 is a cross-sectional view showing a transistor included in the gate driver of FIG. 5. Meanwhile, the configurations described with reference to FIG. 6 may be substantially the same as some of the configurations described with reference to FIG. 3 except for the second transistor TR2. Therefore, overlapping explanations may be omitted or simplified.

Referring to FIG. 6, the gate driver GIC may include the second transistor TR2.

The second transistor TR2 may be located on the buffer layer BF. The second transistor TR2 may include a second source electrode SE2, a second drain electrode DE2, a second active pattern ACT2, and a second gate electrode GE2.

The second active pattern ACT2 may be located on the buffer layer BF. The second active pattern ACT2 may include a silicon-based semiconductor material or an oxide-based semiconductor material. For example, the silicon-based semiconductor material included in the second active pattern ACT2 may include amorphous silicon, polycrystalline silicon, and the like. In addition, the oxide-based semiconductor material included in the second active pattern ACT2 is zinc oxide (ZnOx), tin oxide (SnOx), indium oxide (InOx), indium-zinc oxide (IZO), and indium. May include gallium oxide (Indium Gallium Oxide (IGO)), zinc-tin oxide (ZnSnxOy), and indium-gallium-zinc oxide (IGZO). These may be used alone or in combination with each other.

The second active pattern ACT2 may include a second source region SF2, a second drain region DF2, and a second channel region CH2 located between the second source region SF2 and the second drain region DF2. The second source region SF2 and the second drain region DF2 may be doped with impurity ions. For example, the second source region SF2 and the second drain region DF2 may be doped with P-type impurity ions. That is, the second transistor TR2 may be a PMOS transistor. For another example, the second source region SF2 and the second drain region DF2 may be doped with N-type impurity ions. That is, the second transistor TR2 may be an NMOS transistor.

The first interlayer insulating layer ILD1 may be located on the buffer layer BF covering the second active pattern ACT2.

The second gate electrode GE2 may be located on the first interlayer insulating layer ILD1. The second gate electrode GE2 may overlap the second channel region CH2 on a plane. The second gate electrode GE2 may include a conductive material. For example, the second gate electrode GE2 may include metal, alloy, conductive metal oxide, transparent conductive material, and the like.

The second interlayer insulating layer ILD2 may be located on the first interlayer insulating layer ILD1 covering the second gate electrode GE2. The second interlayer insulating layer ILD2 may include a silicon compound, a metal oxide, and the like.

The second source electrode SE2 and the second drain electrode DE2 may be located on the second interlayer insulating layer ILD2. For example, the second source electrode SE2 and the second drain electrode DE2 may be electrically connected to the second active pattern ACT2 respectively. For example, the second source electrode SE2 may contact the second source region SF2, and the second drain electrode DE2 may contact the second drain region DF2. The signal transmitted to the second source electrode SE2 may be transmitted to the second drain electrode DE2 through the second active pattern ACT2. The second source electrode SE2 and the second drain electrode DE2 may include metal, alloy, conductive metal oxide, transparent conductive material, and the like.

According to some embodiments, charges may accumulate under the second active pattern ACT2 due to polarization of the first substrate SUB1 and/or the second substrate SUB2. For example, charges may be accumulated under of the second channel region CH2 of the second active pattern ACT2. Accordingly, the electrical characteristics (eg, threshold voltage, electron mobility) of the second transistor TR2 may be changed.

For example, when the second transistor TR2 is a PMOS transistor, the bottom panel BP is positively charged so that the first substrate SUB1 and/or the second substrate SUB2 have a negative charge at the bottom, as positive charges accumulate at the top of the first substrate SUB1 and/or the second substrate SUB2, negative charges may accumulate at the bottom of the second active pattern ACT2. Accordingly, the threshold voltage of the second transistor TR2 may be negatively shifted.

For another example, when the second transistor TR2 is an NMOS transistor, the bottom panel BP is negatively charged so that the first substrate SUB1 and/or the second substrate SUB2 are positively charged at the bottom, as negative charges are accumulated at the top of the first substrate SUB1 and/or the second substrate SUB2, positive charges may be accumulated at the bottom of the second active pattern ACT2. Accordingly, the threshold voltage of the second transistor TR2 may be positively shifted. For example, when light (for example, external light) reaches the gate driver GIC, light spots, and the like may occur in the display area DA due to changes in electrical characteristics of the second transistor TR2 caused by a polarization phenomenon of the first substrate SUB1 and/or the second substrate SUB2. Accordingly, the display quality of the display device DD may deteriorate.

According to embodiments, the width W1 of each of the cutout areas CO included in the bottom panel BP in the first direction D1 may be about 160 um or less. For example, the width W1 of each of the cutout areas CO in the first direction D1 on a plane may be about 1 μm to about 160 μm. Accordingly, the phenomenon of light irradiated through the cutout areas CO reaching the gate driver GIC may be reduced or prevented. Accordingly, changes in electrical characteristics of the second transistor TR2 due to polarization of the first substrate SUB1 and/or the second substrate SUB2 may be reduced or prevented. Accordingly, the light spotting, and the like may be reduced or prevented, and the display quality of the display device DD may be improved.

Meanwhile, according to embodiments, the width W1 of each of the cutout areas CO included in the bottom panel BP in the first direction D1 may be preferably about 100 μm to about 160 μm, more preferably about 150 um to about 160 um. When the width W1 of each of the cutout areas CO in the first direction D1 satisfies the above-mentioned range, the light irradiated through the cutout areas CO may be further reduced or prevented. Accordingly, the display quality of the display device DD may be further improved.

Additionally, according to embodiments, each of the cutout areas CO adjacent to the gate driver GIC and the gate driver GIC are aligned in the first direction D1 with the separation distance DT. That is, the separation distance DT may be about 280 μm or more. For example, the separation distance DT may be about 280 μm to about 1000 μm, preferably about 280 μm to about 350 μm, and more preferably about 280 μm to about 300 μm.

when each of the cutout areas CO adjacent to the gate driver GIC Among the cutout areas CO is spaced apart from the gate driver GIC satisfying the above-mentioned range, the path through which light irradiated through CO to reach the gate driver GIC may increase. Accordingly, the phenomenon of light irradiated through the cutout areas CO reaching the gate driver GIC may be further reduced or prevented. Accordingly, changes in electrical characteristics of the second transistor TR2 due to polarization of the first substrate SUB1 and/or the second substrate SUB2 may be further reduced or prevented. Accordingly, the light spotting, and the like may be further reduced or prevented, and the display quality of the display device DD may be further improved.

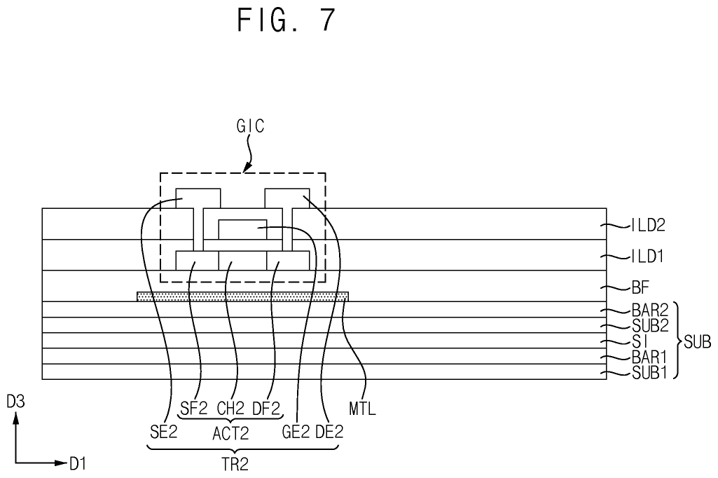

FIG. 7 is a cross-sectional view showing another example of FIG. 6.

Configurations described with reference to FIG. 7 may be substantially the same as some of the configurations described with reference to FIG. 6 except for a metal layer MTL. Therefore, overlapping explanations may be omitted or simplified.

Referring to FIG. 7, according to some embodiments, a metal layer MTL may be additionally located below the second transistor TR2 of the gate driver GIC.

The metal layer MTL may be located on the substrate SUB and covered by the buffer layer BF. For example, the metal layer MTL is located below the second active pattern ACT2, and at least a portion of the metal layer MTL may overlap the second active pattern ACT2 on a plane.

Examples of materials that may be included in the metal layer MTL may be molybdenum (Mo), aluminum (AI), platinum (Pt), palladium (Pd), silver (Ag), magnesium (Mg), gold (Au), and nickel (Ni), neodymium (Nd), iridium (Ir), chromium (Cr), calcium (Ca), titanium (Ti), tantalum (Ta), tungsten (W), copper (Cu), and the like. These may be used alone or in combination with each other.

According to the embodiments described with reference to FIG. 7, as the metal layer MTL is located below the second active pattern ACT2, even if some of the light reaches an area adjacent to the gate driver GIC through the cutout areas (CO, see FIGS. 4 and 5), it may be blocked by the metal layer MTL and may not reach the gate driver GIC. Accordingly, the phenomenon of light irradiated through the cutout areas CO reaching the gate driver GIC may be further reduced or prevented. Accordingly, changes in electrical characteristics of the second transistor TR2 due to polarization of the first substrate SUB1 and/or the second substrate SUB2 may be further reduced or prevented. Accordingly, the light spotting, and the like may be further reduced or prevented, and the display quality of the display device DD may be further improved.

Although aspects of some embodiments and implementations have been described herein, other embodiments and modifications will be apparent from this description. Accordingly, embodiments according to the present disclosure are not limited to such embodiments, but rather are defined by the appended claims, and their equivalents.

What is claimed is:

1. A display device comprising:
a display panel including a display area and a surrounding area surrounding the display area;
a gate driver in the surrounding area of the display panel; and
a bottom panel below the display panel and including a cutout area having a width in a range of 1 micrometers (μm) to 160 μm in a first direction in a plan view.

2. The display device of claim 1, wherein the gate driver and the cutout area are spaced apart from each other in the first direction in the plan view.

3. The display device of claim 2, in the plan view, a separation distance between the gate driver and the cutout area in the first direction is in a range of 280 μm to 1000 μm.

4. The display device of claim 3, wherein the separation distance is in a range of 1.75 to 1000 times the width of the cutout area in the first direction.

5. The display device of claim 1, wherein a width of the cutout area in the first direction is smaller than a width of the cutout area in a second direction intersecting the first direction.

6. The display device of claim 1, further comprising:
an alignment mark in the surrounding area of the display panel, and
wherein a number of the alignment mark and a number of the cutout area are the same.

7. The display device of claim 6, wherein the alignment mark and the cutout area correspond one-to-one.

8. The display device of claim 6, wherein the alignment mark and the cutout area overlap in the plan view.

9. The display device of claim 1, wherein the cutout area is spaced apart from the display area in the first direction in the plan view with the gate driver interposed therebetween.

10. The display device of claim 1, wherein a planar area of the bottom panel is smaller than a planar area of the display panel.

11. The display device of claim 1, wherein the gate driver includes at least one transistor, and
the transistor includes an active pattern including a semiconductor material.

12. The display device of claim 11, wherein the gate driver includes a PMOS transistor.

13. The display device of claim 11, wherein the gate driver includes an NMOS transistor.

14. The display device of claim 11, wherein the display panel further includes a substrate below the active pattern, and
the substrate includes:
a first substrate;
a first barrier layer on the first substrate;
a second substrate on the first barrier layer; and
a second barrier layer on the second substrate.

15. The display device of claim 14, wherein the first substrate and the second substrate include polyimide.

16. A display device comprising:
a display panel including a display area and a surrounding area surrounding the display area;
a gate driver in the surrounding area of the display panel and including at least one transistor including an active pattern including a semiconductor material;
a metal layer below the active pattern and at least a portion of the metal layer overlaps the active pattern in a plan view; and
a bottom panel below the display panel and including a cutout area having a width in a range of 1 micrometer (μm) to 160 μm in a first direction in the plan view.

17. The display device of claim 16, wherein the display panel further includes a substrate below the active pattern, and
the substrate includes:
a first substrate;
a first barrier layer on the first substrate;
a second substrate on the first barrier layer; and
a second barrier layer on the second substrate,
the metal layer is between the second barrier layer and the active pattern.

18. The display device of claim 16, wherein the gate driver and the cutout area are spaced apart in the first direction in the plan view,
a separation distance between the gate driver and the cutout area in the first direction is in a range of 280 micrometers (μm) to 1000 μm in the plan view.

19. The display device of claim 18, wherein the separation distance is in a range of 1.75 to 1000 times the width of the cutout area in the first direction.

20. The display device of claim 16, wherein a width of the cutout area in the first direction is smaller than a width of the cutout area in a second direction intersecting the first direction.
